(19) United States
(12) Patent Application Publication
(10) Pub. No.: US 2026/0129952 A1
(43) Pub. Date: May 7, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Tefu YEH, Kaohsiung (TW); Chun-Cheng CHOU, Taichung (TW)

(21) Appl. No.: 18/934,325

(22) Filed: Nov. 1, 2024

(51) Int. Cl. H01L 21/8238; H01L 21/28; H01L 27/092; H01L 29/06; H01L 29/423; H01L 29/49; H01L 29/66; H01L 29/775; H01L 29/786

(52) U.S. Cl. CPC H10D 84/038; H10D 30/014; H10D 30/43; H10D 30/6735; H10D 30/6739; H10D 30/6757; H10D 62/121; H10D 64/01318; H10D 64/017; H10D 84/0177; H10D 84/85

(57) ABSTRACT

Embodiments of the present disclosure provide a semiconductor device structure and methods of forming the same. The method includes forming first and second fin structures, the first fin structure includes a first plurality of semiconductor layers, and the second fin structure includes a second plurality of semiconductor layers. The method further includes depositing a gate dielectric layer around a portion of each semiconductor layer of the first and second pluralities of semiconductor layers, depositing a sacrificial layer on the gate dielectric layer, removing a first portion of the sacrificial layer disposed on a first portion of the gate dielectric layer around the first plurality of semiconductor layers, selectively depositing a first work function layer on the portion of the gate dielectric layer, and removing a second portion of the sacrificial layer disposed on a second portion of the gate dielectric layer around the second plurality of semiconductor layers.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, and 6 are perspective views of various stages of manufacturing a semiconductor device structure, in accordance with some embodiments.

FIGS. 7A, 8A, 9A, 10A, and 11A are cross-sectional side views of various stages of manufacturing the semiconductor device structure taken along line A-A of FIG. 6, in accordance with some embodiments.

FIGS. 7B, 8B, 9B, 10B, and 11B are cross-sectional side views of various stages of manufacturing the semiconductor device structure taken along line B-B of FIG. 6, in accordance with some embodiments.

FIGS. 7C, 8C, 9C, 10C, and 11C are cross-sectional side views of various stages of manufacturing the semiconductor device structure taken along line C-C of FIG. 6, in accordance with some embodiments.

FIGS. 12A, 12B, 12C, 12D, 12E, 12F, 12G, 12H, and 12I are cross-sectional side views of various stages of manufacturing the semiconductor device structure, in accordance with some embodiments.

FIG. 13 is a cross-sectional side view of one of various stages of manufacturing the semiconductor device structure taken along line A-A of FIG. 6, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

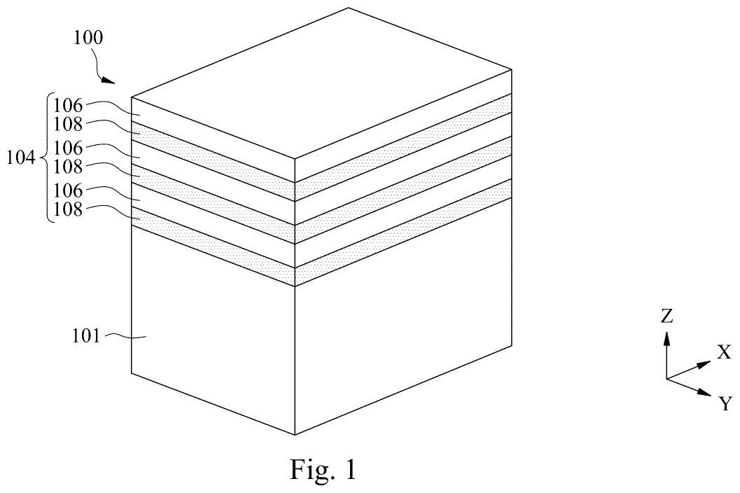

FIG. 1-13 show exemplary processes for manufacturing a semiconductor device structure 100 according to embodiments of the present disclosure. It is understood that additional operations can be provided before, during, and after processes shown by FIG. 1-13, and some of the operations described below can be replaced or eliminated, for additional embodiments of the method. The order of the operations/processes is not limiting and may be interchangeable.

FIG. 1-6 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongated shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 3 nm and about 9 nm. Each second semiconductor layer 108 may have a thickness that is equal, less, or greater than the thickness of the first semiconductor layer 106. In some embodiments, each second semiconductor layer 108 has a thickness in a range between about 4 nm and about 14 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. In some embodiments, the number of first semiconductor layers 106 ranges from two to 10.

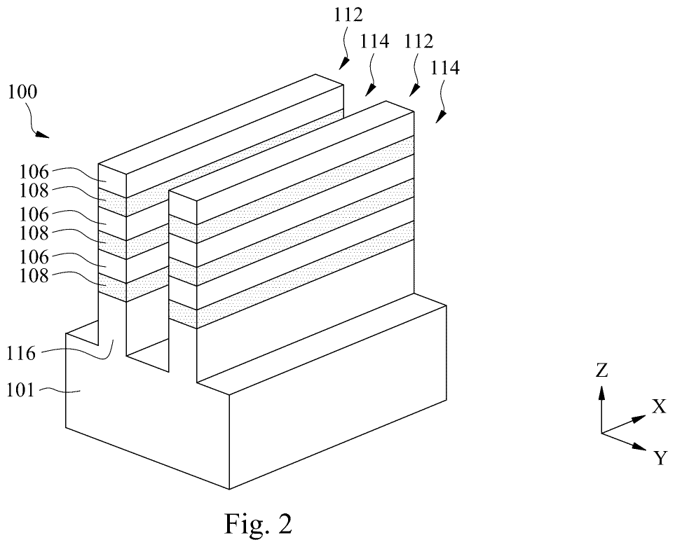

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

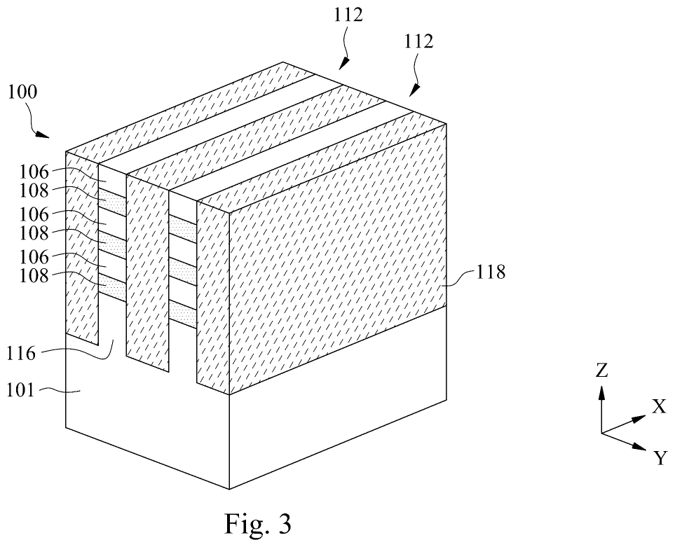

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

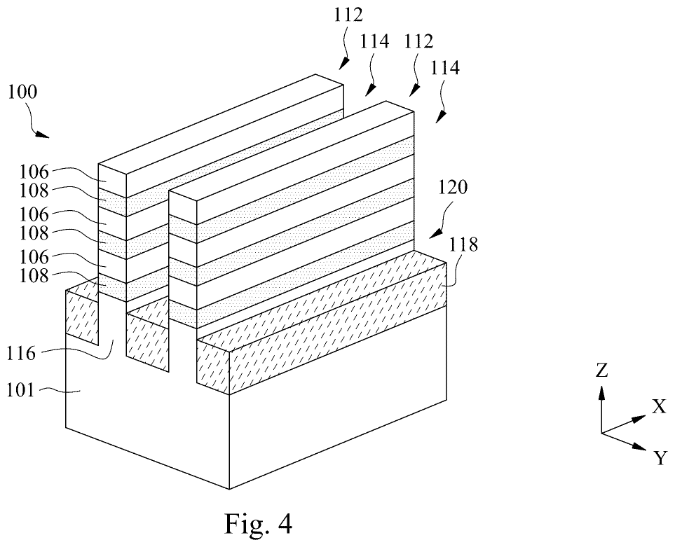

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101.

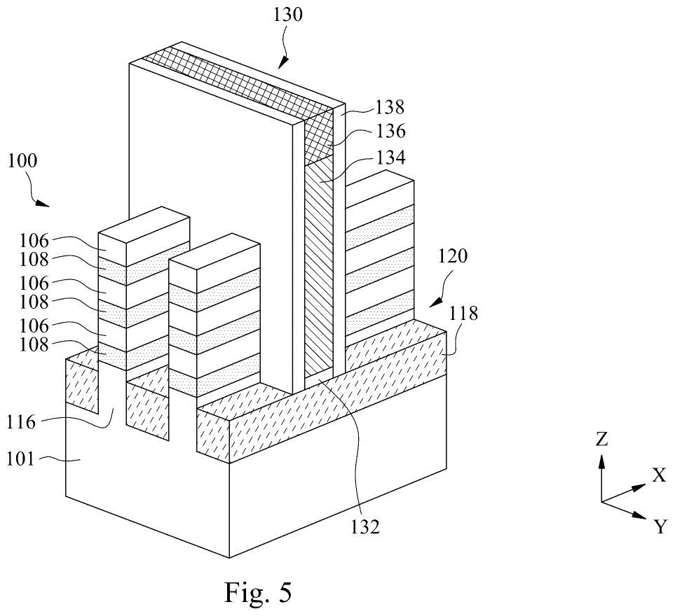

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. In some embodiments, the gate spacers 138 are also formed on sidewalls of the exposed portions of the fin structures 112. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device structure 100.

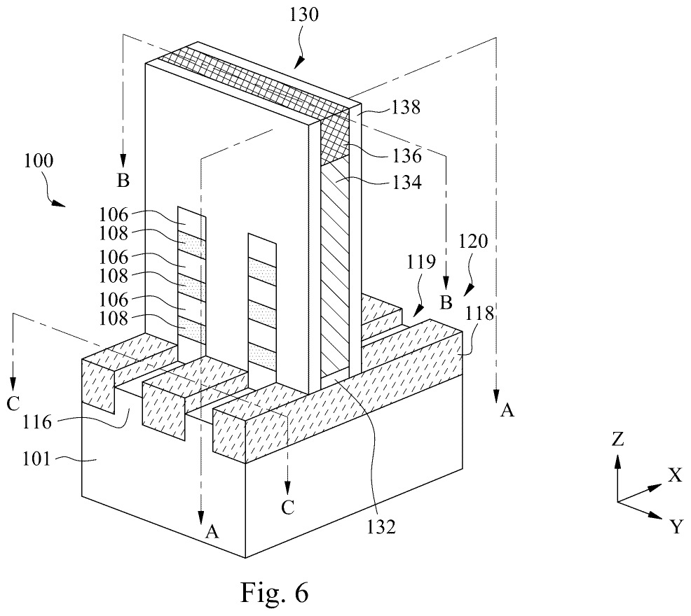

In FIG. 6, the portions of the fin structures 112 not covered by the sacrificial gate structure 130 and the gate spacers 138 are recessed to a level above, at, or below the top surfaces of the isolation regions 120. The recess of the portions of the fin structures 112 can be done by an etch process, either isotropic or anisotropic etch process, and the etch process may be selective with respect to the first and second semiconductor layers 106, 108. The etch process may be a dry etch, such as a RIE, NBE, or the like, or a wet etch, such as using tetramethyalammonium hydroxide (TMAH), ammonium hydroxide (NH₄OH), or any suitable etchant.

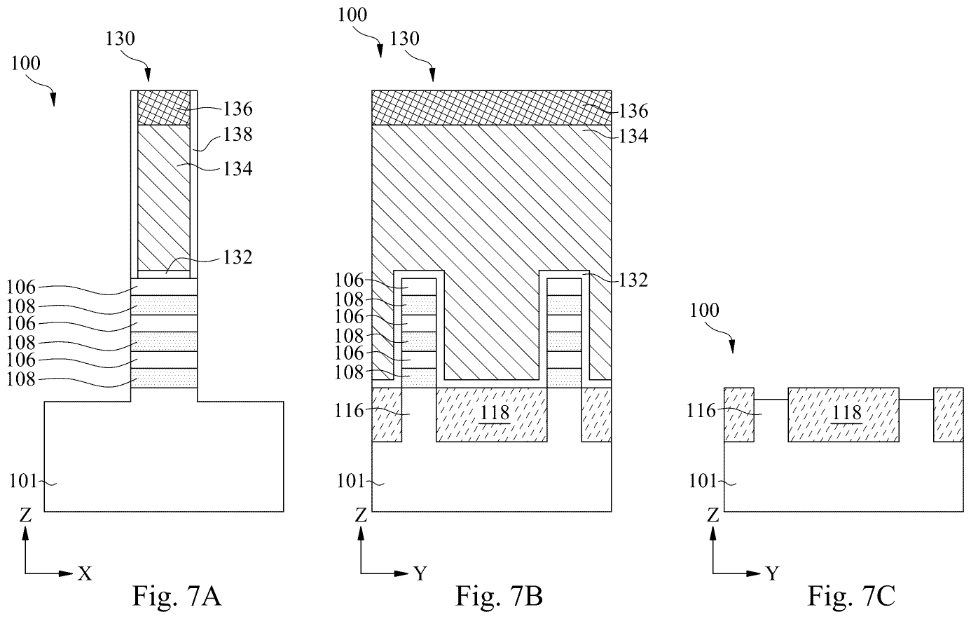

FIGS. 7A, 7B, and 7C are cross-sectional side views of the semiconductor device structure 100 taken along line A-A, line B-B, and line C-C of FIG. 6, respectively.

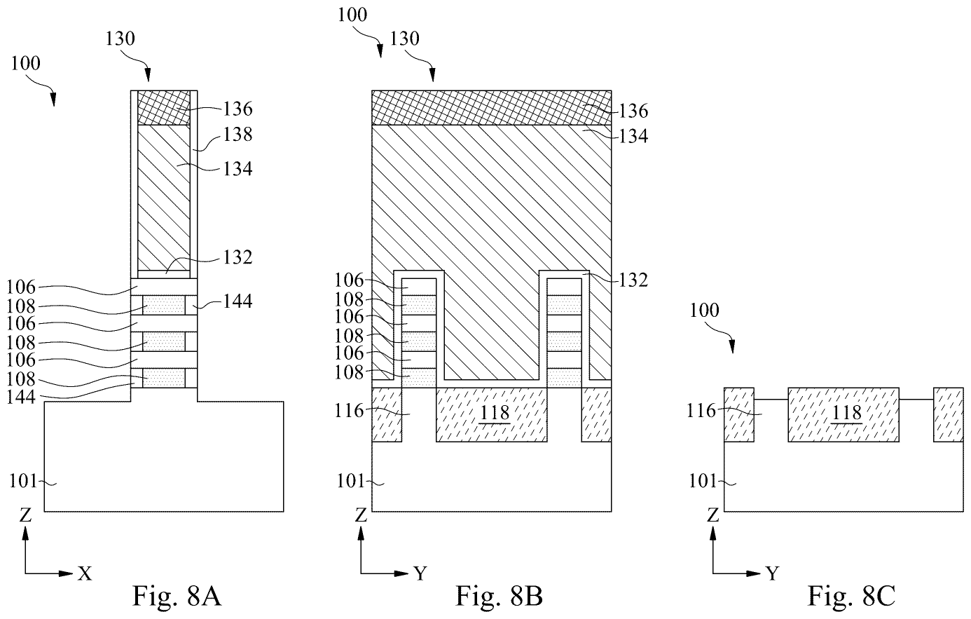

FIGS. 8A, 8B, and 8C are cross-sectional side views of one of various stages of manufacturing the semiconductor device structure 100 taken along line A-A, line B-B, and line C-C of FIG. 6, respectively, in accordance with some embodiments. As shown in FIG. 8A, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layers 108, a dielectric layer is deposited in the cavities to form dielectric spacers 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected by the first semiconductor layers 106 during the anisotropic etching process. The remaining second semiconductor layers 108 are capped between the dielectric spacers 144 along the X direction.

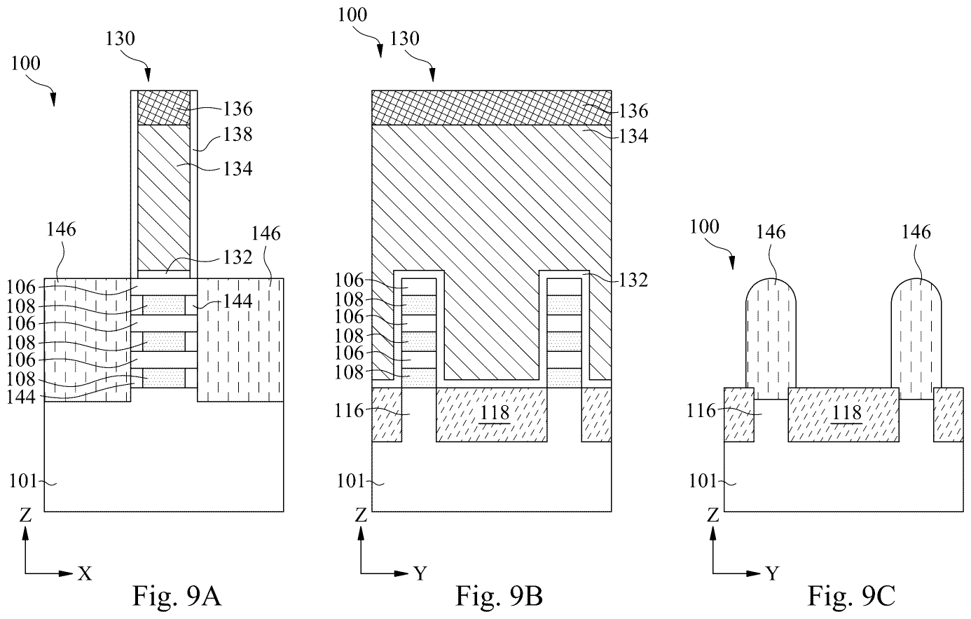

FIGS. 9A, 9B, and 9C are cross-sectional side views of one of various stages of manufacturing the semiconductor device structure 100 taken along line A-A, line B-B, and line C-C of FIG. 6, respectively, in accordance with some embodiments. As shown in FIGS. 9A and 9C, source/drain (S/D) regions 146 are formed from the substrate portion 116. The S/D regions 146 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE.

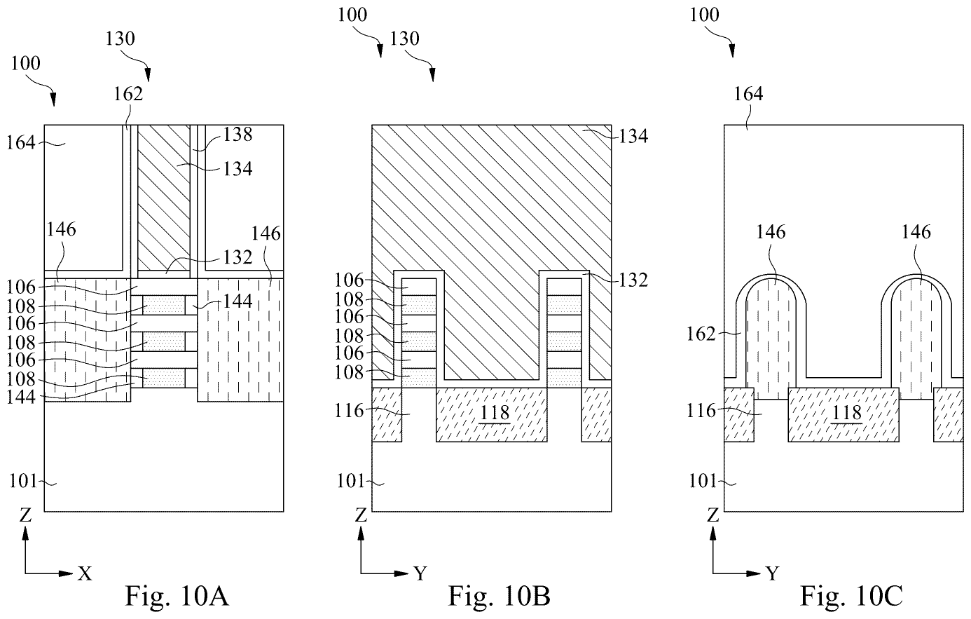

FIGS. 10A, 10B, and 10C are cross-sectional side views of one of various stages of manufacturing the semiconductor device structure 100 taken along line A-A, line B-B, and line C-C of FIG. 6, respectively, in accordance with some embodiments. In FIGS. 10A, 10B, and 10C, a contact etch stop layer (CESL) 162 is conformally formed on the exposed surfaces of the semiconductor device structure 100. The CESL 162 covers the sidewalls of the sacrificial gate structure 130, the insulating material 118, and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIGS. 10A and 10B.

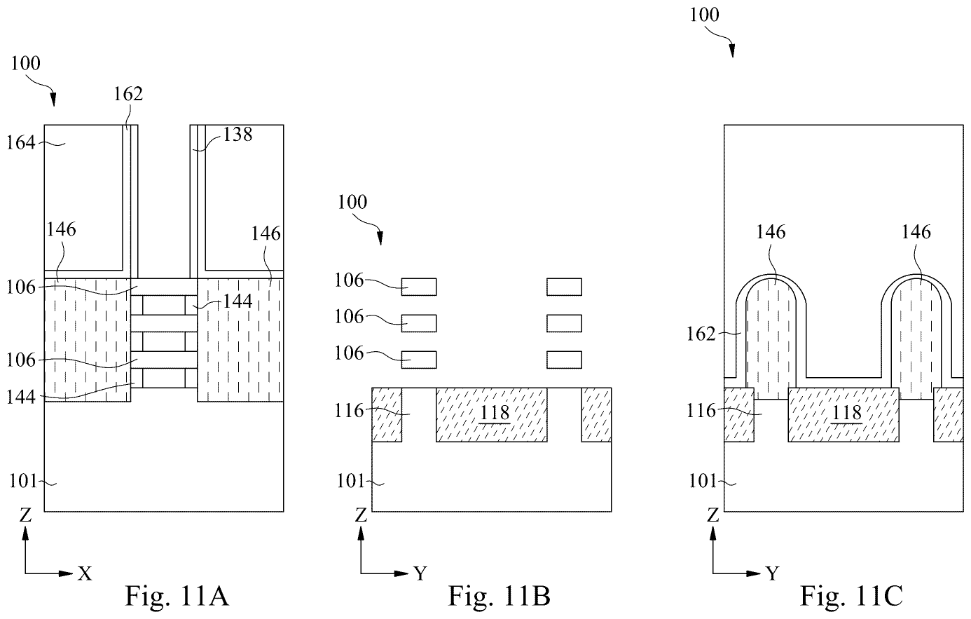

FIGS. 11A, 11B, and 11C are cross-sectional side views of one of various stages of manufacturing the semiconductor device structure 100 taken along line A-A, line B-B, and line C-C of FIG. 6, respectively, in accordance with some embodiments. As shown in FIGS. 11A and 11B, the sacrificial gate structure 130 and the second semiconductor layers 108 are removed. The removal of the sacrificial gate structure 130 and the semiconductor layers 108 forms an opening between gate spacers 138 and between first semiconductor layers 106. The ILD layer 164 protects the S/D regions 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the ILD layer 164, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the gate spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

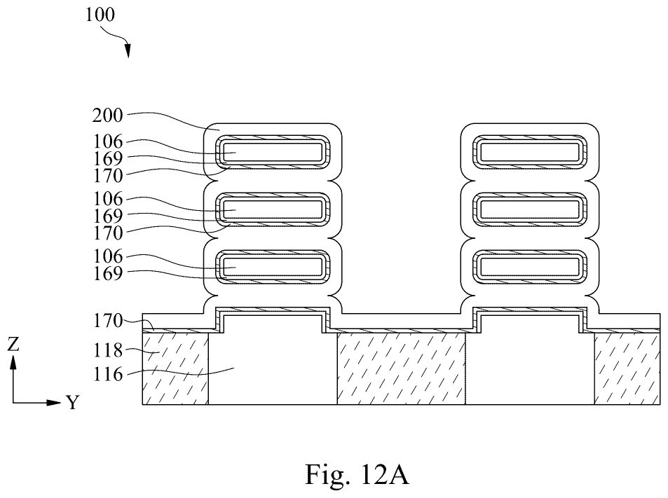

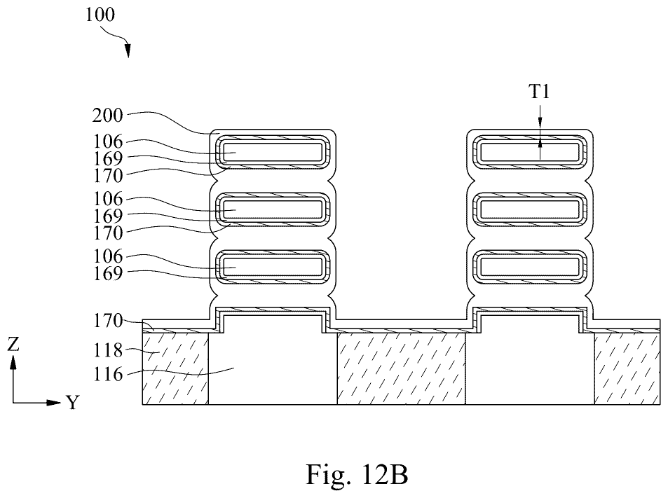

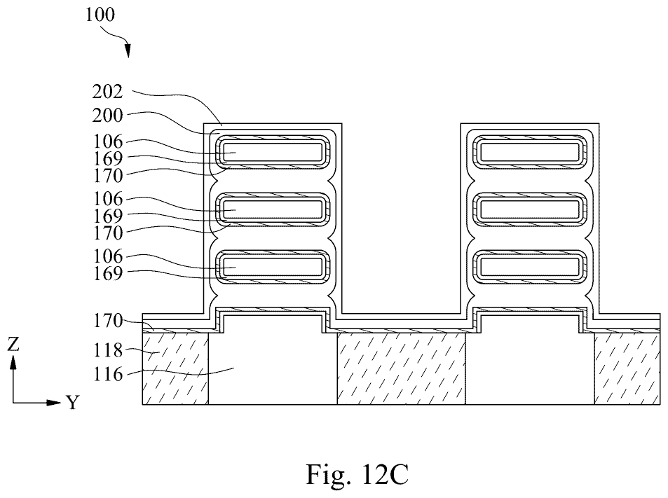

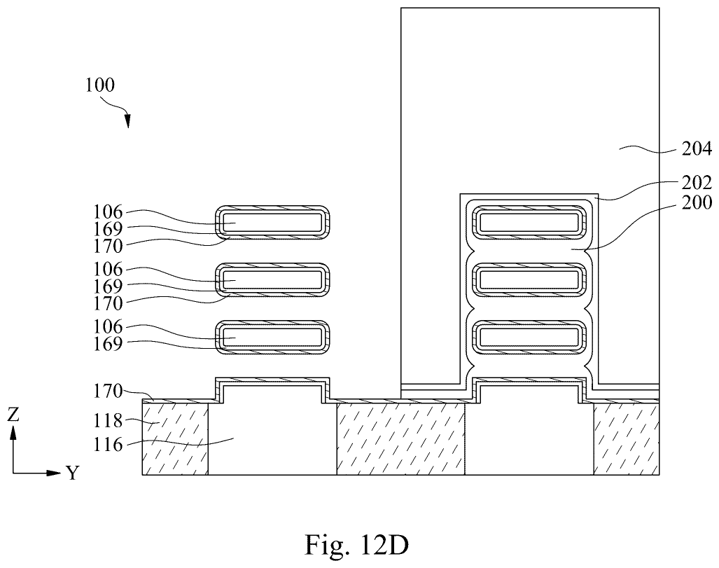

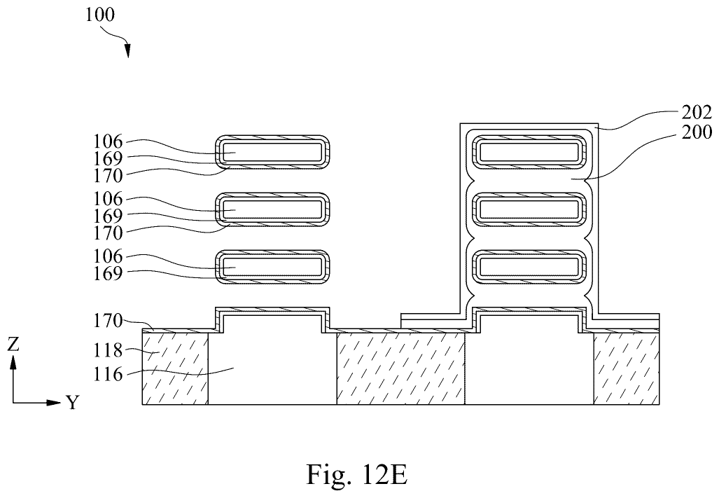

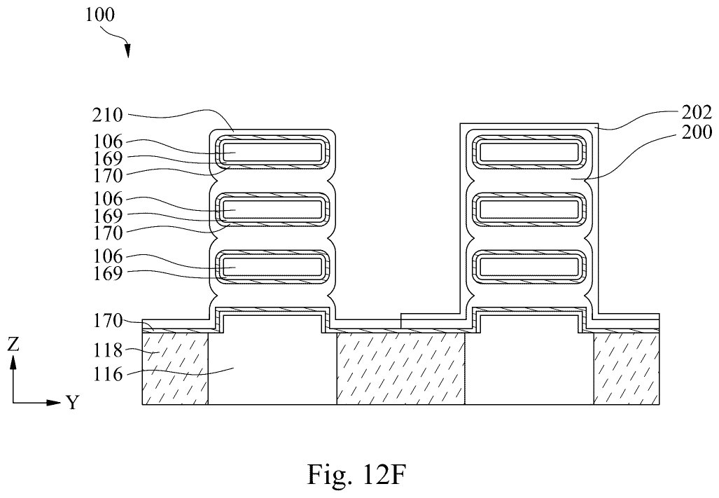

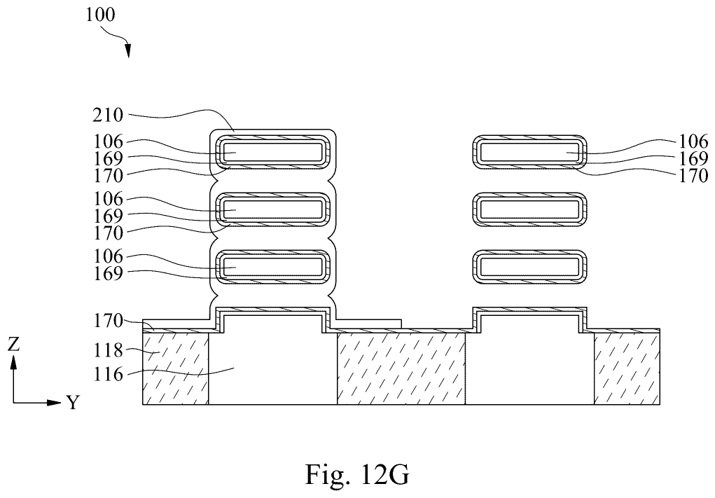

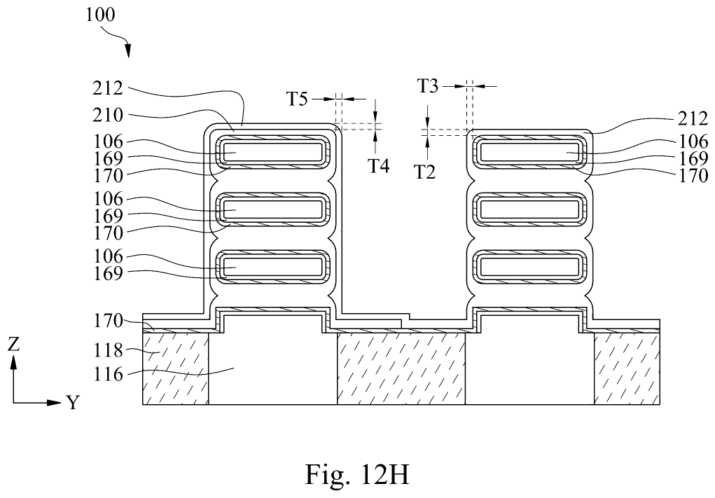

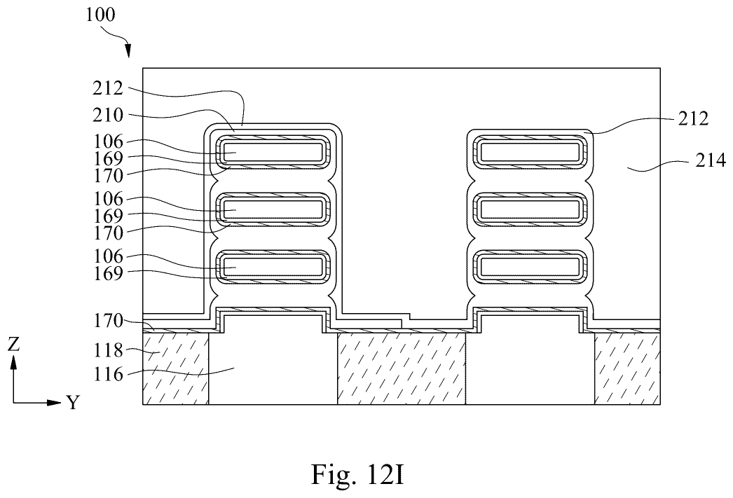

FIG. 12A-12J are cross-sectional side views of various stages of manufacturing the semiconductor device structure 100, in accordance with some embodiments. As shown in FIG. 12A, after the formation of the nanostructure channels (i.e., the exposed portions of the first semiconductor layers 106), an interfacial layer (IL) 169 is formed to surround the exposed portions of the first semiconductor layers 106 and the substrate portion 116, and a gate dielectric layer 170 is formed on the IL 169. In some embodiments, the IL 169 is selectively formed on the semiconductor materials of the first semiconductor layers 106 and the substrate portion 116, and the gate dielectric layer 170 is also formed on the insulating material 118. In some embodiments, the IL 169 is an oxide layer, such as silicon oxide. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. In some embodiments, the gate dielectric layer 170 has a thickness ranging from about 0.5 nm to about 3 nm.

In some embodiments, the first semiconductor layers 106 located on the left side of FIG. 12A are channels of an NMOS device, which is located in an NMOS region, and the first semiconductor layers 106 located on the right side of FIG. 12A are channels of a PMOS device adjacent the NMOS device. The PMOS device is located in a PMOS region.

In some embodiments, a dipole process is performed to introduce dipole materials into the gate dielectric layer 170. The dipole process may include depositing a dipole layer (not shown) on the gate dielectric layer 170 and performing a thermal process to drive the dipole material in the dipole layer into the gate dielectric layer 170. In some embodiments, different dipole layers are formed for NMOS devices and PMOS devices. For example, a dipole material suitable for NMOS devices may include lanthanoid oxide (La₂O₃), yttrium oxide (Y₂O₃), titanium oxide (TiO₂), other n-type dipole material, or combinations thereof; and a dipole material suitable for PMOS devices may include aluminum oxide (Al₂O₃), TiO₂, other p-type dipole material, or combinations thereof. After the thermal process, the dipole layer is removed to expose the gate dielectric layer 170.

In some embodiments, after the formation of the gate dielectric layer 170 (and the dipole process in some embodiments), a sacrificial layer 200 is deposited on the gate dielectric layer 170, as shown in FIG. 12A. The sacrificial layer 200 is made of or includes a material different from the material of the gate dielectric layer 170. In some embodiments, the sacrificial layer 200 includes a metal oxide, such as aluminum oxide (AlOₓ), where x is an integer or non-integer. Aluminum oxide may be removed by a wet etch process using ammonia solution as an etchant, and the ammonia solution does not affect the gate dielectric layer 170. In some embodiments, the ammonia solution is ammonium hydroxide having about one weight percent to about two weight percent of ammonia. Other materials, such as zinc oxide, gallium oxide, or titanium nitride, may be used for the sacrificial layer 200. The sacrificial layer 200 may be formed by any suitable process. In some embodiments, the sacrificial layer 200 is formed by a conformal process, such as ALD. The sacrificial layer 200 is formed to fill the gaps between vertically adjacent first semiconductor layers 106. Thus, in some embodiments, the sacrificial layer 200 has a thickness greater than about 2 nm, such as from about 2.5 nm to about 4 nm. If the thickness of the sacrificial layer 200 is less than about 2 nm, gaps may be formed between vertically adjacent first semiconductor layer 106, and subsequently formed blocking layer 202 (FIG. 12C) may be formed in the gaps, which is difficult to remove. On the other hand, if the thickness of the sacrificial layer 200 is greater than about 4 nm, subsequent removal of the sacrificial layer 200 may have an unnecessarily long time duration.

In FIG. 12B, an etch back process is performed on the sacrificial layer 200. In some embodiments, a wet etch process is performed to etch back the sacrificial layer 200. The wet etch process reduces the thickness of the portions of the sacrificial layer 200 located over the topmost first semiconductor layers 106 and the insulating material 118. The thickness of the portions of the sacrificial layer 200 located adjacent sidewalls of the first semiconductor layers 106 may be also reduced. The wet etch process does not remove portions of the sacrificial layer 200 located between vertically adjacent first semiconductor layers 106. In some embodiments, the thickness T1 of the portion of the sacrificial layer 200 located over the topmost first semiconductor layer 106 is reduced to about 1.2 to about 1.8 nm. As a result, the time duration of the subsequent removal of the sacrificial layer 200 may be reduced.

In FIG. 12C, a blocking layer 202 is formed on the sacrificial layer 200. In some embodiments, the blocking layer 202 is a self-assembled monolayer (SAM) including a polymer having silicon, carbon, nitrogen, oxygen, or a combination thereof. In some embodiments, the SAM includes a main chain containing benzyl or epoxy, and the main chain has a molecular weight between about 30 and about 100. The SAM also includes terminal functional groups, such as benzyl, amine, hydroxyl, sulfone, or phosphorous. The terminal functional groups are functionalized to enhance deposition selectivity of the following deposition process. For example, the terminal functional groups prevent the precursors of the following deposition process from adhering thereto. In some embodiments, the following deposition process is to deposit an n-type work function layer, and the blocking layer 202 prevents the n-type work function layer from formed thereon.

In FIG. 12D, a patterned mask layer 204 is formed to cover the portion of the blocking layer 202 disposed in the PMOS region, and the portion of the blocking layer 202 disposed in the NMOS region and the portion of the sacrificial layer 200 located thereunder are removed. In some embodiments, the patterned mask layer 204 is a patterned photoresist layer. The patterned mask layer 204 may be formed by first forming a mask layer in the NMOS and PMOS regions followed by removing the portion of the mask layer formed in the NMOS region to expose the portion of the blocking layer 202 disposed in the NMOS region. The exposed portion of the blocking layer 202 may be removed by any suitable process. In some embodiments, a dry etch process, such as a plasma etch process, is performed to remove the exposed portion of the blocking layer 202. The plasma etch process may damage the gate dielectric layer 170 if the gate dielectric layer 170 is exposed, and the sacrificial layer 200 protects the gate dielectric layer 170 during the plasma etch process. As described above, the sacrificial layer 200 fills the gaps between vertically adjacent first semiconductor layers 106 to prevent the blocking layer 202 from forming in the gaps. If the blocking layer 202 is formed in the gaps between vertically adjacent first semiconductor layers 106, it would be difficult to remove using the plasma etch process.

The removal of the portion of the blocking layer 202 disposed on the NMOS device exposes the portion of the sacrificial layer 200 located thereunder. Next, the exposed portion of the sacrificial layer 200 is removed. The exposed portion of the sacrificial layer 200 may be removed by any suitable process. In some embodiments, the exposed portion of the sacrificial layer 200 is removed by a wet etch process using ammonia as etchant. The wet etch process does not affect the gate dielectric layer 170 disposed under the exposed portion of the sacrificial layer 200. The portion of the blocking layer 202 disposed in the PMOS region is protected by the patterned mask layer 204 during the removal of the portions of the blocking layer 202 and sacrificial layer 200.

In FIG. 12E, the patterned mask layer 204 is removed to expose the portion of the blocking layer 202 disposed in the PMOS region. In some embodiments, the patterned mask layer 204 is removed by a plasma ash process using oxygen-containing plasma. The oxygen-containing plasma can oxidize n-type work function layer or p-type work function layer. Thus, in some embodiments, the removal of the patterned mask layer 204 is performed without the presence of any work function layers. The plasma ash process does not affect the exposed gate dielectric layer 170 disposed on the NMOS device.

In FIG. 12F, an n-type work function layer 210 is selectively deposited on the NMOS device. The n-type work function layer 210 may include any suitable n-type work function material, such as Ti, Al, Ag, Mn, Zr, TiAl, TiAlC, TaC, TaCN, TaSiN, TaAl, TaAlC, TiAlN, other n-type work function material, or combinations thereof. In some embodiments, the n-type work function layer 210 is made of or includes an aluminum-containing material, such as TiAl, TiAlC, TaAl, TaAlC, TiAlN. In some embodiments, the n-type work function layer 210 has a thickness ranging from about 0.5 nm to about 20 nm. The n-type work function layer 210 is not formed in the PMOS region. As described above, the blocking layer 202 inhibits the deposition of the precursors of the n-type work function layer 210. The n-type work function layer 210 may be a conformal layer formed by a conformal process, such as ALD.

In some embodiments, after the formation of the n-type work function layer 210, an optional cap layer (not shown) may be selectively formed on the n-type work function layer 210. The cap layer may include any suitable material. In some embodiments, the cap layer is made of or includes the same material as the p-type work function layer 212 (FIG. 12H). The blocking layer 202 prevents the cap layer from depositing thereon.

In FIG. 12G, the blocking layer 202 and the sacrificial layer 200 disposed in the PMOS region are removed. The blocking layer 202 may be removed by the plasma etch process described in FIG. 12D, and the sacrificial layer 200 may be removed by the wet etch process described in FIG. 12D. The plasma etch process and the wet etch process may not substantially affect the n-type work function layer 210 (or the cap layer). Thus, there is no need to form a patterned mask layer on the n-type work function layer 210. As a result, the n-type work function layer 210 would not be damaged by the oxygen-containing plasma in the plasma ash process to remove the patterned mask layer. The removal of the blocking layer 202 and the sacrificial layer 200 exposes the gate dielectric layer 170, as shown in FIG. 12G.

In FIG. 12H, a p-type work function layer 212 is deposited on the exposed gate dielectric layer 170 and on the n-type work function layer 210 (or the cap layer). The p-type work function layer 212 may include any suitable p-type work function material, such as TiN, TaN, Ru, Mo, Al, WN, ZrSi₂, MoSi₂, TaSi₂, NiSi₂, WN, other p-type work function material, or combinations thereof. In some embodiments, the p-type work function layer 212 is made of or includes TiN. The p-type work function layer 212 may be a formed by any suitable process, such as PVD or ALD. In some embodiments, the portion of the p-type work function layer 212 deposited on the horizontal surface of the gate dielectric layer 170 has a thickness T2, the portion of the p-type work function layer 212 deposited on the vertical surface of the gate dielectric layer 170 has a thickness T3, the portion of the p-type work function layer 212 deposited on the horizontal surface of the n-type work function layer 210 (or the cap layer) has a thickness T4, and the portion of the p-type work function layer 212 deposited on the vertical surface of the n-type work function layer 210 (or the cap layer) has a thickness T5. In some embodiments, the thickness T2 ranges from about 0.7 nm to about 5 nm, the thickness T3 ranges from about 0.5 nm to about 5 nm, the thickness T4 ranges from about 0.5 nm to about 5 nm, and the thickness T5 ranges from about 0.3 nm to about 5 nm. In some embodiments, the thickness T4 is greater than the thickness T5, and the difference between the thicknesses T4 and T5 may range from 0 to about 0.2 nm. In some embodiments, the thickness T2 is greater than the thickness T3, and the difference between the thicknesses T2 and T3 may range from 0 to about 0.2 nm. In some embodiments, the thickness T2 is greater than the thickness T4, and the difference between the thicknesses T2 and T4 may range from 0 to about 0.2 nm.

In some embodiments, the p-type work function layer 212 deposited in the PMOS region is free of aluminum, because the p-type work function layer 212 is deposited after the deposition of the n-type work function layer 210. In other words, no more deposition of the n-type work function layer 210 after the deposition of the p-type work function layer 212. The PMOS device with the p-type work function layer 212 that is free of aluminum has an improved tunning of the threshold voltage.

In FIG. 12I, a bulk metal fill 214 is formed over the p-type work function layer 212 in the NMOS and PMOS regions. The bulk metal fill 214 is made of or includes aluminum, copper, titanium, tantalum, tungsten, cobalt, molybdenum, combinations thereof, or other suitable metal. The bulk metal fill 214 may be formed by CVD, ALD, electro-plating, or other suitable deposition technique. The n-type work function layer 210, the p-type work function layer 212, and the bulk metal fill 214 located in the NMOS region may be referred to as a gate electrode layer 172, and the p-type work function layer 212 and the bulk metal fill 214 located in the PMOS region may be referred to as a gate electrode layer 172. The gate electrode layers may be also deposited over the upper surface of the ILD layer 164 (FIG. 11A). The gate electrode layer formed over the ILD layer 164 is then removed by using, for example, CMP, until the top surface of the ILD layer 164 is exposed.

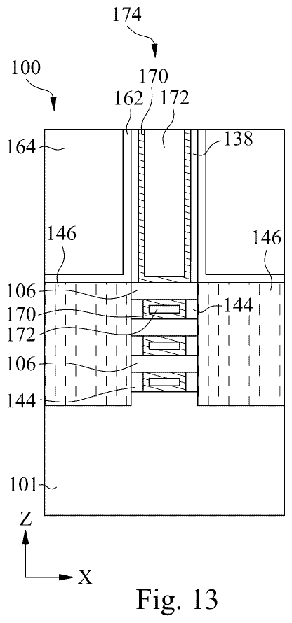

FIG. 13 is a cross-sectional side view of one of various stages of manufacturing the semiconductor device structure 100 taken along line A-A of FIG. 6, in accordance with some embodiments. As shown in FIG. 13, the gate electrode layer 172, which includes the n-type work function layer 210, the p-type work function layer 212, and the bulk metal fill 214 located in the NMOS region, or the p-type work function layer 212 and the bulk metal fill 214 located in the PMOS region, is disposed on the gate dielectric layer 170. The IL 169 is omitted in FIG. 13 for clarity. The IL 169 (not shown), the gate dielectric layer 170, and the gate electrode layer 172 may be collectively referred to as a gate structure 174.

Embodiments of the present disclosure provide a method to form a semiconductor device structure 100. The method includes depositing a sacrificial layer 200 on the gate dielectric layer 170 in the NMOS and PMOS regions, depositing a blocking layer 202 on the sacrificial layer 200 in the NMOS and PMOS regions, removing portions of the blocking layer 202 and the sacrificial layer 200 located in the NMOS region, selectively depositing an n-type work function layer 210 in the NMOS region, removing the blocking layer 202 and the sacrificial layer 200 located in the PMOS region, and depositing a p-type work function layer 212 in the PMOS region and the NMOS region. Some embodiments may achieve advantages. For example, the sacrificial layer 200 protects the gate dielectric layer 170 during the removal of the portion of the blocking layer 202 in the NMOS region. Furthermore, by depositing the p-type work function layer 212 after depositing the n-type work function layer, the p-type work function layer 212 is free of aluminum. As a result, improved tunning of the threshold voltage is achieved.

An embodiment is a method. The method includes forming first and second fin structures from a substrate, the first fin structure includes a first plurality of semiconductor layers, and the second fin structure includes a second plurality of semiconductor layers. The method further includes depositing a gate dielectric layer around a portion of each semiconductor layer of the first and second pluralities of semiconductor layers, depositing a sacrificial layer on the gate dielectric layer, removing a first portion of the sacrificial layer disposed on a first portion of the gate dielectric layer around the first plurality of semiconductor layers, selectively depositing a first work function layer on the first portion of the gate dielectric layer, removing a second portion of the sacrificial layer disposed on a second portion of the gate dielectric layer around the second plurality of semiconductor layers, depositing a second work function layer over the first work function layer and the second portion of the gate dielectric layer, and depositing a bulk metal fill on the second work function layer.

Another embodiment is a method. The method includes forming a first fin structure in an NMOS region and a second fin structure in a PMOS region of a substrate, the first fin structure includes a first plurality of semiconductor layers, and the second fin structure includes a second plurality of semiconductor layers. The method further includes depositing a gate dielectric layer around a portion of each of the first and second pluralities of semiconductor layers in the NMOS and PMOS regions, depositing a sacrificial layer on the gate dielectric layer in the NMOS and PMOS regions, forming a blocking layer on the sacrificial layer in the PMOS region, removing the sacrificial layer in the NMOS region to expose the gate dielectric layer in the NMOS region, selectively depositing an n-type work function layer on the exposed gate dielectric layer in the NMOS region, depositing a p-type work function layer over the n-type work function layer in the NMOS region and over the gate dielectric layer in the PMOS region, and depositing a bulk metal fill over the p-type work function layer.

A further embodiment is a semiconductor device structure. The structure includes a first semiconductor layer disposed in an NMOS region of a substrate, a second semiconductor layer disposed in a PMOS region of the substrate, a gate dielectric layer surrounding at least a portion of the first semiconductor layer and at least a portion of the second semiconductor layer, an n-type work function layer surrounding the gate dielectric layer in the NMOS region, and a p-type work function layer disposed around the n-type work function layer in the NMOS region. The p-type work function layer surrounds the gate dielectric layer in the PMOS region, and the p-type work function layer is free of aluminum. The structure further includes a bulk metal fill disposed on the p-type work function layer in the NMOS region and the PMOS region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method, comprising:
forming first and second fin structures from a substrate, wherein the first fin structure includes a first plurality of semiconductor layers, and the second fin structure includes a second plurality of semiconductor layers;
depositing a gate dielectric layer around a portion of each semiconductor layer of the first and second pluralities of semiconductor layers;
depositing a sacrificial layer on the gate dielectric layer;
removing a first portion of the sacrificial layer disposed on a first portion of the gate dielectric layer around the first plurality of semiconductor layers;
selectively depositing a first work function layer on the first portion of the gate dielectric layer;
removing a second portion of the sacrificial layer disposed on a second portion of the gate dielectric layer around the second plurality of semiconductor layers;
depositing a second work function layer over the first work function layer and the second portion of the gate dielectric layer; and
depositing a bulk metal fill on the second work function layer.

2. The method of claim 1, wherein the sacrificial layer comprises a metal oxide.

3. The method of claim 2, wherein the metal oxide comprises aluminum oxide, zinc oxide, or gallium oxide.

4. The method of claim 1, wherein selectively depositing of the first work function layer comprises depositing a blocking layer on the sacrificial layer.

5. The method of claim 4, wherein the blocking layer comprises a self-assembled monolayer.

6. The method of claim 4, wherein selectively depositing of the first work function layer further comprises forming a patterned mask layer on a first portion of the blocking layer disposed around the second plurality of semiconductor layers.

7. The method of claim 6, wherein selectively depositing of the first work function layer further comprises removing a second portion of the blocking layer disposed on the first portion of the sacrificial layer.

8. The method of claim 7, further comprising removing the patterned mask layer by a plasma ash process.

9. A method, comprising:
forming a first fin structure in an NMOS region and a second fin structure in a PMOS region of a substrate, wherein the first fin structure includes a first plurality of semiconductor layers, and the second fin structure includes a second plurality of semiconductor layers;
depositing a gate dielectric layer around a portion of each of the first and second pluralities of semiconductor layers in the NMOS and PMOS regions;
depositing a sacrificial layer on the gate dielectric layer in the NMOS and PMOS regions;
forming a blocking layer on the sacrificial layer in the PMOS region;
removing the sacrificial layer in the NMOS region to expose the gate dielectric layer in the NMOS region;
selectively depositing an n-type work function layer on the exposed gate dielectric layer in the NMOS region;
depositing a p-type work function layer over the n-type work function layer in the NMOS region and over the gate dielectric layer in the PMOS region; and
depositing a bulk metal fill over the p-type work function layer.

10. The method of claim 9, wherein the sacrificial layer comprises a metal oxide.

11. The method of claim 10, wherein the metal oxide comprises aluminum oxide.

12. The method of claim 11, wherein the n-type work function layer comprises TiAlC, and the p-type work function layer comprises TiN.

13. The method of claim 9, wherein the blocking layer comprises a self-assembled monolayer.

14. The method of claim 9, further comprising etching back the sacrificial layer prior to forming the blocking layer.

15. The method of claim 14, wherein a thickness of the sacrificial layer ranges from about 2.5 nm to about 4 nm prior to the etching back, and the thickness is reduced to about 1.2 nm to about 1.8 nm after the etching back.

16. The method of claim 9, further comprising removing the sacrificial layer in the PMOS region prior to the depositing of the p-type work function layer.

17. A semiconductor device structure, comprising:
a first semiconductor layer disposed in an NMOS region of a substrate;
a second semiconductor layer disposed in a PMOS region of the substrate;
a gate dielectric layer surrounding at least a portion of the first semiconductor layer and at least a portion of the second semiconductor layer;
an n-type work function layer surrounding the gate dielectric layer in the NMOS region;
a p-type work function layer disposed around the n-type work function layer in the NMOS region, wherein the p-type work function layer surrounds the gate dielectric layer in the PMOS region, and the p-type work function layer is free of aluminum; and
a bulk metal fill disposed on the p-type work function layer in the NMOS region and the PMOS region.

18. The semiconductor device structure of claim 17, wherein the n-type work function layer comprises TiAlC, and the p-type work function layer comprises TiN.

19. The semiconductor device structure of claim 18, wherein the p-type work function layer has a first portion disposed on a horizontal surface of the gate dielectric layer in the PMOS region, a second portion disposed on a vertical surface of the gate dielectric layer in the PMOS region, a third portion disposed on a horizontal surface of the n-type work function layer, and a fourth portion disposed on a vertical surface of the n-type work function layer.

20. The semiconductor device structure of claim 19, wherein the first portion has a first thickness, the second portion has a second thickness, the third portion has a third thickness, the fourth portion has a fourth thickness, and the first thickness is different from the second thickness.
